(19) United States
(12) Patent Application Publication
(10) Pub. No.: US 2003/0122218 A1
(43) Pub. Date: Jul. 3, 2003

(54) MULTILAYER CHIP INDUCTOR

(76) Inventor: Ming-Tzung Lee, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/030,000

(22) Filed: Dec. 31, 2001

(51) Int. Cl. H01L 29/00

(52) U.S. Cl. 257/531

(57) ABSTRACT

An improved multilayer chip inductor comprises a plurality of sheets which are multilayered. The main feature is that the internal layer of the sheet is made of magnetic material (or nonmagnetic material), and nonmagnetic material (or magnetic material) is printed on the location at proper proportion near the internal electrode circuit according to electric characteristic. The multilayered elements described above are co-fired into a ceramic package chip by low temperature co-fire ceramic technology such that an unshielded area is remained. The unshielded area can cause open magnetic line of force to improve current carry capability of the chip inductor. Further, the relation between inductance and current carry capability can be properly controlled according to the portion of remained unshielded area.

### BACKGROUND OF THE INVENTION

1. Field of the Invention

The present invention relates to an improved multilayer chip inductor, especially to a new one made of several ceramic materials co-fired and the manufacturing method thereof. The present invention also utilizes the unshielded characteristic of the nonmagnetic material to make the magnetic lines of force leak such that current carry capability can be enhanced.

2. Description of the Prior Art

Current carry capability is one of important electrical specifications of electric elements. However, inductance is usually inversely proportional to current carry capability.

As shown in FIG. 1 and FIG.2, commonly seen inductors are composed of an upper cover 4, a lower cover 6 and several sheets 5, all of above-mentioned parts belonging to soft ferrite magnetic materials. Internal electrodes 51 are printed on the sheets 5 via simple process and can be protected by shielding feature such that a multilayer chip inductor having shielding feature can be formed. However, in the closed magnetic field, disadvantages of reaching magnetic saturation easily and poor current carry capability are resulted in.

From what mentioned above, the commonly used objects still have many disadvantages and are really not perfect designs requiring improvement.

The inventor of the present invention ruminated over the disadvantages resulted from the commonly used objects, and earnestly deliberated the way of improvement and innovation. After studying hard for a long period, the inventor eventually succeeded in inventing the present invention.

### SUMMARY OF THE INVENTION

The purpose of the present invention is to provide an improved multilayer chip inductor utilizing co-fired ceramic technology to remain a non-shielding area, which can cause open magnetic line of force to improve current carry capability, on the surface of the packaging element. Moreover, the relation between the inductance and current carry capability can be adequately controlled according to the proportion of the non-shielding area.

The improved multilayer chip inductor reaching the above-mentioned purpose is performed by utilizing the present low temperature co-fired ceramic (LTCC) technology, with determine a plurality of species of ceramic materials (such as magnetic material and nonmagnetic material due to real design requirement.

### BRIEF DESCROPTION OF THE DRAWINGS

The drawings disclose an illustrative embodiment of the present invention which serves to exemplify the various advantages and objects hereof, and are as follows:

FIG. 1 is the decomposed diagram of the commonly used multilayer chip inductor;

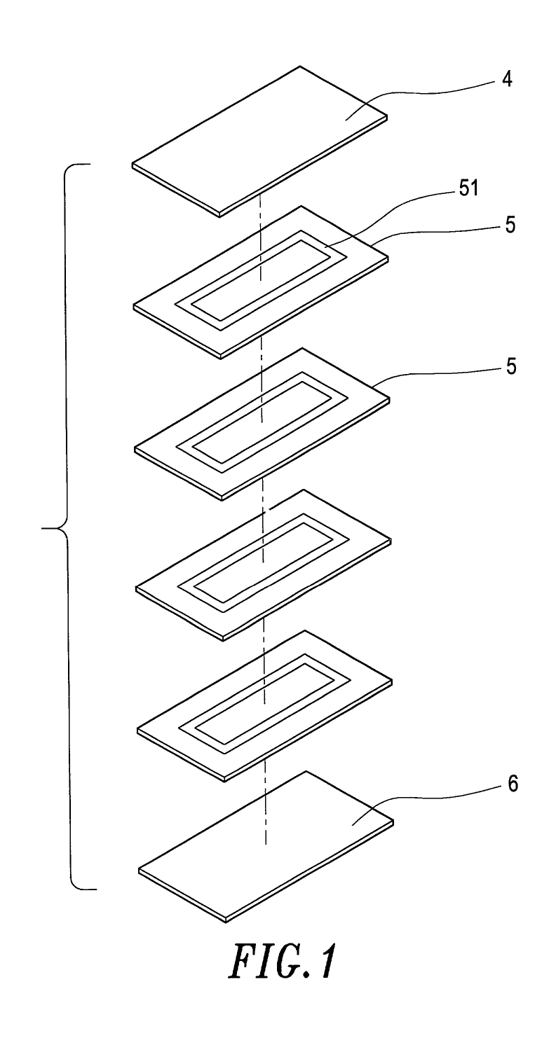

FIG. 2 is the manufacturing procedures of commonly used multilayer chip inductor;

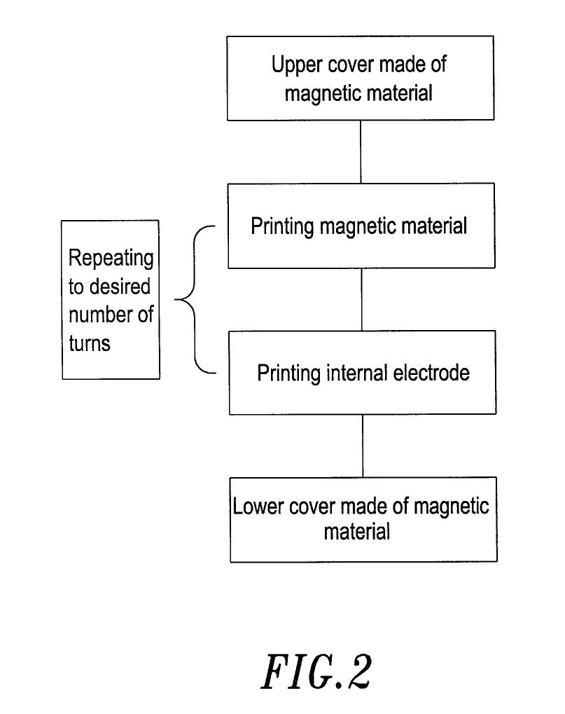

FIG. 3 is the decomposed diagram of the present invention, the multilayer chip inductor;

FIG. 4 is manufacturing procedures of present invention, the multilayer chip inductor;

### DIAGRAM REMARKS

1 Upper cover sheet

2 Sheet

21 Internal layer

22 Internal electrode

23 External frame

3 Lower cover sheet

4 Upper cover

5 Sheet

51 Internal electrode

6 Lower cover

### DETAILED DESCRIPTION OF THE PREFERRED EMBODIMENT

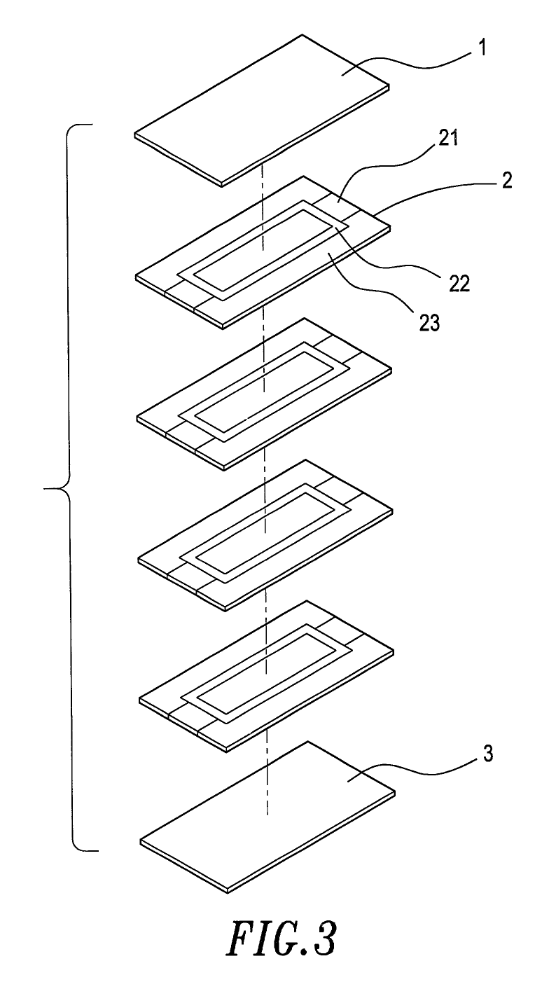

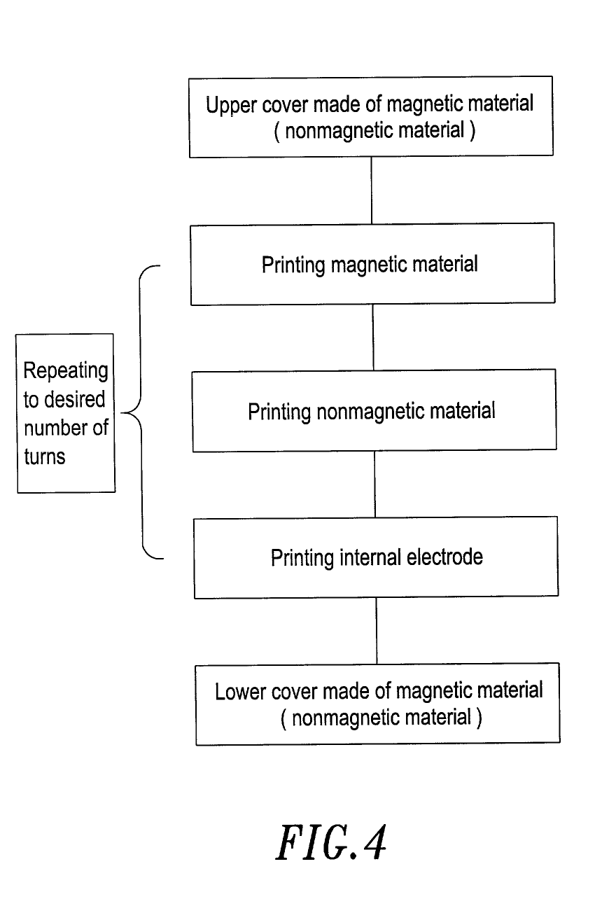

Referring to FIG. 3, FIG. 4, the multilayer chip inductor provided from the present invention is composed of an upper cover sheet 1, the lower cover sheet 3, both of them made of magnetic material (or nonmagnetic material), and several sheets 2 multilayered between them. The amount of the sheets 2 is in accordance with required number, and the main feature is:

For each sheet 2, the internal layer 21 thereon is made of magnetic material (or nonmagnetic material), while the external frame 23 at both sides thereon is printed with nonmagnetic material (or magnetic material) oppositely. Moreover, a circuit-like internal electrode 22 is formed at the proper location of the portion connecting the internal layer 21 and external frame 23. The magnetic material and nonmagnetic material are respectively printed on the internal layer 21 and the external frame 23 of the sheet 2, or vice versa, to determine magnetism and non-magnetism to co-fire a ceramic packaging chip.

The material of the upper cover, lower cover and the sheet can be selected as magnetic material or nonmagnetic material due to design requirements. By making the above mentioned elements multilayered, and using low temperature co-fired ceramic (LTCC) technology, an unshielded area is remained on the packaging surface to result in open magnetic line of force such that current carry capability of the chip inductor can be improved. Further, according to the proportion of remaining unshielded area, the relation between the inductance and the current carry capability can be properly controlled. Table 1 lists the measured current carry capability corresponding to different inductance with comparing the commonly used inductor and the inductor of the present invention. The table shows that under the same inductance, current carry capability of the inductor of the present invention is much higher than that of the commonly used inductor. The comparison interprets that the present invention really can improve the current carry capability of the chip inductor and have great progress.

★This is the electric characteristic comparison of the example at the size:3.2X1.6X1.1

TABLE 1
Comparison of the current carry capability of the
commonly used inductor and the inductor of the present invention

IDC(mA)

| | Common- | Present |
|---|---|---|
| L(uH) | ly Used | invention |
| 0.18 | 250 | 350 |
| 0.22 | 250 | 350 |
| 0.27 | 250 | 350 |
| 0.33 | 200 | 300 |
| 0.39 | 200 | 300 |
| 0.47 | 150 | 250 |
| 0.56 | 150 | 250 |
| 0.68 | 150 | 250 |
| 0.82 | 100 | 180 |
| 1.0 | 100 | 180 |
| 1.2 | 50 | 100 |
| 1.5 | 50 | 100 |
| 1.8 | 50 | 100 |
| 2.2 | 50 | 100 |
| 2.7 | 50 | 100 |
| 3.3 | 50 | 100 |
| 3.9 | 50 | 100 |
| 4.7 | 50 | 100 |
| 5.6 | 25 | 75 |
| 6.8 | 25 | 75 |
| 8.2 | 25 | 75 |
| 10 | 25 | 50 |
| 12 | 15 | 30 |
| 15 | 5 | 20 |

Comparing with above mentioned commonly used technology, the improved 10 multilayer chip inductor has following advantages:

1. With co-fired ceramic technology, the unshielded area remained on the packaging surface can cause open magnetic line of force to improve the current carry capability of the chip inductor.

2. The chip inductor formed by co-firing several species of ceramic materials and the manufactured method thereof is presented. According to the principle of unshielded characteristic of the nonmagnetic material causing magnetic line of force to leak out, current carry capability is enhanced.

Many changes and modifications in the above described embodiment if the invention can, of course, be carried out without departing from the scope thereof. Accordingly, to promote the progress in science and the useful arts, the invention is disclosed and is intended to be limited only by the scope of appended claims.

What is claimed is:

1. an improved multilayer chip inductor composed of a plurality of sheets multilayered between an upper cover sheet and a lower cover sheet, having a plurality of features that:
an internal layer of each of said sheets is made of magnetic material while nonmagnetic material is oppositely printed at a position of proper proportion of an external frame at both sides of said internal layer according to a requirement of electrical characteristic, an circuit-like internal electrode formed at a proper location of connecting portion of magnetic and nonmagnetic material; and
said upper cover sheet, said lower cover sheet and said plurality of sheets are multilayered and co-fired as a ceramic packaging chip by low temperature co-fired ceramic technology such that an unshielded area is remained on a packaging surface, said unshielded area causing open magnetic line of force to improve current carry capability of said chip inductor.

2. an improved multilayer chip inductor as recited in claim 1, wherein said internal layer can also be made of nonmagnetic material while said external frame is printed with magnetic material to determine magnetism and non-magnetism to co-fire a ceramic packaging chip.

3. an improved multilayer chip inductor as recited in claim 1, wherein said upper cover sheet and said lower cover sheet can be made of magnetic material and nonmagnetic material according to design requirements.
